(19) United States
(12) Patent Application Publication
(10) Pub. No.: US 2019/0383529 A1
(43) Pub. Date: Dec. 19, 2019

(54) METHOD FOR OPERATING A THERMOELECTRIC MODULE

(71) Applicant: Mahle International GmbH, Stuttgart (DE)

(72) Inventors: Juergen Gruenwald, Ludwigsburg (DE); Peter Hinderer, Stuttgart (DE); Julien Mercier, Gerlingen (DE); Thomas Pfadler, Stuttgart (DE)

(21) Appl. No.: 16/440,970

(22) Filed: Jun. 13, 2019

(30) Foreign Application Priority Data
Jun. 15, 2018 (DE) 10 2018 209 648.1
Aug. 23, 2018 (DE) 10 2018 214 258.0

(51) Int. Cl. F25B 21/04; H01L 35/02; H01L 35/28; H03H 7/01

(52) U.S. Cl. CPC F25B 21/04; H03H 7/0115; H01L 35/28; H01L 35/02

(57) ABSTRACT

A method for operating a thermoelectric module may include creating a pulse width modulated control signal for controlling the thermoelectric module, converting the control signal into an operating signal having a direct voltage portion and an alternating voltage portion, and supplying the operating signal for operating the thermoelectric module to the thermoelectric module. The method may also include tapping the operating signal on the thermoelectric module and determining an electrical resistance of the thermoelectric module therefrom.

### CROSS-REFERENCE TO RELATED APPLICATIONS

This application claims priority to German Patent Application No. DE 10 2018 209 648.1, filed on Jun. 15, 2018, and to German Patent Application No. DE 10 2018 214 258.0, filed on Aug. 23, 2018, the contents of both of which are hereby incorporated by reference in their entirety.

### TECHNICAL FIELD

The present invention relates to a method for operating a thermoelectric module, which is controlled and operated by means of a pulse width modulated control signal. The invention furthermore relates to a thermoelectric device comprising a thermoelectric module, which is operated in such a way.

### BACKGROUND

Thermoelectric modules are electrically supplied and pump heat during operation, so that they have a cold side as well as a warm side. The electrical supply can on principle occur by applying a direct voltage to the module. For the simplified conversion and/or control, it is also known to control and to thus operate or supply, respectively, such modules by means of a pulse width modulated signal. Pulse width modulated signals can generally consist of a direct voltage portion and an alternating voltage portion. Due to the fact that the alternating voltage portion can negatively impact the efficiency of the module, it is known to provide a filter between a signal generator of the pulse width modulated control signal and the module, which filter eliminates the alternating voltage portion of the control signal as efficiently as possible.

It is desirable and advantageous to identify operating states, such as the temperature of the cold side and/or the temperature of the warm side and/or a thermal power of the module. On principle, separate sensors can be used for this purpose, which detect, for example, the temperature of the cold side and/or the temperature of the warm side.

U.S. Pat. No. 9,685,599 B2 uses the phases between the pulses of a pulse width modulated signal applied to the module for the operation to identify the Seebeck voltage. In practice, however, this turns out to be unreliable due to the low precision of the identified voltage.

It is also known to perform such measurements, in particular temperature measurements, with the help of open circuit voltage measurements of the module, in that the module for the measurement is separated from the electrical supply, which is required for the operation, also referred to as operating voltage below. Such methods are described, for example, in U.S. Pat. No. 4,639,883 A and GB 2 513 295 B.

It is also known to forgo the use of a separate sensor system in order to identify the operating parameters of the module, for example the temperature of the cold side and/or of the warm side. CA 1 337 304 C describes, for example, the measurement of an internal electrical resistance of the module using an alternating voltage signal and a direct voltage signal, in order to identify the temperature on the cold side and on the warm side of the module.

DE 10 2015 222 357 describes a method, according to which an electrical resistance of the module is captured with the help of a measuring signal, which has a direct voltage portion and an alternating voltage portion, and the temperature of the cold side and of the warm side of the module and corresponding cooling capacities and heating capacities can be identified or estimated, respectively, based on this electrical resistance. The creation or generation, respectively, of the measuring signal thereby takes place by means of a separate generator, which also requires a driver stage.

In particular the use of a separate sensor system for the identification of the state variables of the module, in particular of the temperatures on the cold side and/or the warm side or the separation of the modules from the operating voltage for the purpose of determining these variables is disadvantageous in the case of the method for operating thermoelectric modules, which is known from the prior art.

### SUMMARY

The present invention thus deals with the object of specifying improved or at least different embodiments for a method for operating a thermoelectric module of the above-mentioned type as well as for a device comprising such a thermoelectric module, which are characterized in particular by a simplified identification of an electrical resistance of the module and/or an efficiency increase of the module.

This object is solved according to the invention by means of the subject matters of the independent claim(s). Advantageous embodiments are subject matter of the dependent claim(s).

The present invention is based on the general idea of using a pulse width modulated control signal for operating a thermoelectric module, and to convert this control signal into an operating signal, which has a direct voltage portion and an alternating voltage portion, and to use it to operate the module as well as to identify an electrical resistance of the module. The operating signal is thus used to operate the module and to identify the resistance. This means that a separate measuring signal does not need to be generated to identify the electrical resistance of the module. It is thus possible to implement the method in a simplified manner, in particular without additional generators, amplifiers and the like. It is furthermore not required to perform a separation of the signal, which is necessary for the operation of the thermoelectric module, that is, a separation of the operating signal or of the operating voltage of the module, respectively, for the purpose of identifying the electrical resistance of the module. On the one hand, the electrical resistance of the module can thereby be identified in a simplified manner and, on the other hand, a total efficiency of the module can be improved.

According to the idea of the invention, a pulse width modulated control signal is initially created or generated, respectively, which serves to control the thermoelectric module. This control signal is subsequently converted into an operating signal, which has a direct voltage portion and an alternating voltage portion. The operating signal for operating the module is supplied to the module and thus serves as operating voltage of the module in such a way that the module pumps heat during operation. The operating signal, which has the direct voltage portion and the alternating voltage portion, is additionally tapped on the module, in order to identify the electrical resistance of the module therefrom. The identification of the electrical resistance can thus take place during the running operation of the module. The identification of the electrical resistance can thus in particular take place in real time and thus without operational interruptions of the module.

The solution according to the invention allows realizing the control and thus the operation of the module with the help of a common bridge circuit, in particular a full or half bridge. In addition, the use of separate sensor for the temperature measurement on a warm side or cold side, respectively, of the module is not necessary. A regulation on the basis of the characteristic of the module is furthermore possible.

The features direct voltage portion and alternating voltage portion are to hereinafter be understood as those of the operating signal, unless otherwise specified. The direct voltage portion thus corresponds in particular to the arithmetic average value of the voltage signal of the operating signal, which changes over time.

The operating signal is a time-dependent, electrical voltage signal, which consists of the direct voltage portion and the alternating voltage portion. The voltage signal results in an electrical current signal of the operating signal, which, analogously, consists of a direct voltage portion and an alternating voltage portion. It goes without saying that the above and following information with regard to the electrical voltage can thus be transferred analogously to the electrical current or to the current signal, respectively, and likewise belong to the scope of this invention. To simplify matters, only the electrical voltage will be discussed below.

The operating signal, which is converted from the pulse width modulated control signal, is applied in the electric circuit, into which the thermoelectric module is integrated. The operating signal is thus a function of the electrical resistance of the thermoelectric module, which, in turn, is associated with the temperature on the cold side of the thermoelectric module, hereinafter also referred to as cold side temperature, and with the temperature on the warm side of the thermoelectric module, hereinafter also referred to as warm side temperature. By means of the tapping and measuring of the operating signal on the thermoelectric module, conclusions can thus be drawn to the electrical resistance of the thermoelectric module and/or to the cold side temperature and/or to the warm side temperature of the thermoelectric module.

The electrical resistance of the module is preferably an inner electrical resistance of the module, in particular an impedance of the module. The identification of the resistance thereby allows for the determination of the cold side temperature and/or for the determination of the warm side temperature. These determinations take place, for example, in consideration of the Seebeck effect, in particular as described in CA 1 337 304 C and/or DE 10 2015 222 357 A1.

The frequency of the pulse width modulated control signal can generally be arbitrary. Advantageously, the frequency of the pure sinusoidal signal is up to several 100 kHz. In the case of frequencies of greater than a lower frequency band edge, approximately 1 kHz, thermal effects are suppressed, which are disadvantageous for the service life of the thermoelectric elements. Starting at an upper frequency band edge, approximately 100 kHz, disadvantageous inductive effects result. The frequency band of the pulse width modulated control signal is to be selected in a component-specific manner such that low-frequency thermal effects as well as higher-frequency inductive effects have a negligible impact on the control signal.

The thermoelectric module can generally be designed arbitrarily, provided that it pumps heat during operation. The module can in particular have a Peltier element comprising differently doped semiconductors or can be embodied as such a Peltier element.

The conversion of the control signal into the operating signal occurs, as mentioned above, by means of the conversion of the control signal into the direct voltage portion and the alternating voltage portion. The operating signal thus consists of the time-dependent alternating voltage portion and the constant direct voltage portion and is thus time-dependent.

To identify the electrical resistance of the module, it is advantageously provided to determine, in particular to measure, the current and the voltage for both portions of the operating signal. A measuring means can be provided for this purpose. The respective determination or measurement can generally occur in an any manner. The voltage measurement can in particular occur with the help of a voltage divider. The current measurement can occur with the help of a so-called shunt resistor. Measurements by means of an ADC (analog-digital converter) and the subsequent processing by means of a suitable processing means, for example a processor, are likewise possible. It is conceivable thereby to separate the alternating voltage portion and the direct voltage portion from one another, for example with the help of a suitable filter. It is also conceivable to perform a conversion into an equivalent direct voltage signal, for example with the help of a suitable electric circuit, for the measurement of the alternating voltage portion.

In the case of advantageous embodiments, the conversion of the control signal occurs in such a way that a peak-to-peak value, that is, the absolute difference between, in particular consecutive maximum values and minimum values of the operating voltage, is smaller than the direct voltage portion. The conversion in particular occurs in such a way that a relative amplitude, that is, the ratio between the peak-to-peak value and the amount of the direct voltage portion, is between 0.10 and 0.40. After the conversion, a systematic and predetermined relative amplitude of the operating signal is thus at hand, in order to attain an advantageous operation of the thermoelectric module as well as a simplified and precise identification of the electrical resistance. It is advantageous thereby when the first harmonic is not or partially weakened, whereas the higher harmonics are weakened more strongly, in particular eliminated.

In the case of a preferred embodiment, a filter or a filter means, respectively, in particular a resonant circuit, also referred to as LC filter, is used for converting the control signal into the operating signal. This has the advantage that such filters are already present in the case of thermoelectric modules, which are controlled by means of pulse width modulated control signals, so that they only need to be adapted and no further components for converting the control signal into the operating signal are required. The adaptation occurs in particular in such a way that a predetermined relative amplitude is present after the conversion, so that the operating signal has the predetermined alternating voltage portion.

Embodiments, in the case of which the conversion of the control signal occurs in such a way that the alternating voltage portion of the operating signal has a sinusoidal course, turn out to be advantageous. Such a conversion can in particular occur by means of an adaptation of the filter, for example of the resonant circuit, in particular with regard to the dimensioning. A sinusoidal course of the alternating voltage portion allows for a simplified and/or more precise identification of the electrical resistance and thus in particular of the cold side temperature and/or of the warm side temperature.

Embodiments are advantageous, in the case of which higher harmonics of the pulse width modulated control signal are filtered, preferably eliminated, in response to the conversion of the control signal. This allows for a simplified and more precise identification of the electrical resistance.

The pulse width modulated control signal can generally have an arbitrary duty cycle. The pulse width modulated control signal can in particular have a changing, that is, inconstant, duty cycle. Preferably, the tapped operating signal for identifying the electrical resistance is thereby initially calibrated. Due to the fact that the electrical resistance is a function of the frequency of the alternating voltage portion, the calibration allows for a more exact identification of the electrical resistance.

Embodiments are preferred, in the case of which the duty cycle of the pulse width modulated control signal for identifying the electrical resistance of the module is adjusted for a predetermined time period and thus temporarily to a constant value, whereby this constant value is non-zero. The calibration can thus be simplified. It is thereby in particular not necessary to perform calibrations for several duty cycles. The duty cycle of the pulse width modulated control signal can thus further be varied arbitrarily outside of the identification phases of the electrical resistance. This provides for a more variable operation of the thermoelectric module. It is additionally possible thereby to attain more precise identification of the electrical resistance, even if the alternating voltage portion does not have a sinusoidal course or a course, which deviates from a sinusoidal course, respectively. The duty cycle can be, for example, 30% or 70% and is temporarily adjusted to a value of 50% in order to identify the electrical resistance.

Advantageously, embodiments, in the case of which the time period, in which the duty cycle is adjusted to the predetermined constant value, are selected in such a way that a thermal reaction of the thermoelectric module is negligible in this time period. No or negligible impacts of the operation of the thermoelectric module thus result in such a time period. This means that the operation of the module runs at least largely unchanged, while the identification of the electrical resistance occurs. The time period is, for example, a few milliseconds, in particular between 1 ms and 10 ms.

It is possible, on principle, to perform the measurement of the electrical resistance of the module continuously or in arbitrary time intervals.

Embodiments prove to be advantageous, in the case of which the determination of the resistance occurs in time intervals, which can be up to several seconds, in particular up to 15 s. It has been shown that, due to the thermal inertia of the module, these time intervals, in which the duty cycle can be adjusted to the constant value, are sufficient in order to determine the electrical resistance and thus in particular the cold side temperature and/or the warm side temperature sufficiently exactly.

The identification of the electrical resistance of the module, in particular the determination of the cold side temperature and/or of the warm side temperature, can easily ensure a self-regulation in such a way that the thermal power of the module is changed as a function of the determined warm side temperature and/or cold side temperature. The module can thereby in particular be used in an air conditioning system and the like. It is thereby also possible to use the module in a seat, for example of a vehicle, in a simple manner, and to determine and readjust the cold side temperature and/or the warm side temperature without using separate sensor.

It goes without saying that in addition to the method for operating the thermoelectric module, a thermoelectric device comprising a thermoelectric module, which is operated in such a way, also belongs to the scope of this invention.

The device thereby has the thermoelectric module, which pumps heat during operation and which has the cold side as well as the warm side. The device also has a signal creator or generator, respectively, which creates or generates respectively, the pulse width modulated control signal for operating the module. Between the signal creator and the module, the device also has a filter means, which is embodied in such a way that it converts the pulse width modulated control signal into the operating signal.

The filter means preferably has a resonant circuit, in particular an LC filter. The filter means is in particular embodied as such a resonant circuit.

The device advantageously has a measuring means, which identifies or determines the direct voltage portion as well as the alternating voltage portion of the operating signal as well as the corresponding electrical currents during operation. It is thus possible to identify the electrical resistance of the thermoelectric module.

To perform the method and/or to control the measuring means, the module, the signal creator and possibly the filter means, the device advantageously has a control means, which can be embodied as a microelectronics unit, in particular as a processor.

The creation of the pulse width modulated control signal and the identification of the electrical resistance, in particular the determination of the warm side temperature and/or of the cold side temperature, can occur within the same unit, in particular the same microelectronics or the same processor, respectively. The setup of the device is thus significantly simplified and/or more cost-efficient.

Further important features and advantages of the invention follow from the subclaims, from the drawing, and from the corresponding figure description on the basis of the drawing.

It goes without saying that the above-mentioned features and the features, which will be described below, cannot only be used in the respectively specified combination, but also in other combinations or alone, without leaving the scope of the present invention.

### BRIEF DESCRIPTION OF THE DRAWINGS

Preferred exemplary embodiments of the invention are illustrated in the drawings and will be described in more detail in the following description, whereby identical reference numerals refer to identical or similar or functionally identical components, in which

FIG. 1 shows a circuit diagram-like, highly simplified illustration of a thermoelectric device comprising a thermoelectric module,

FIG. 2 shows an enlarged illustration of a diagram from FIG. 1.

### DETAILED DESCRIPTION

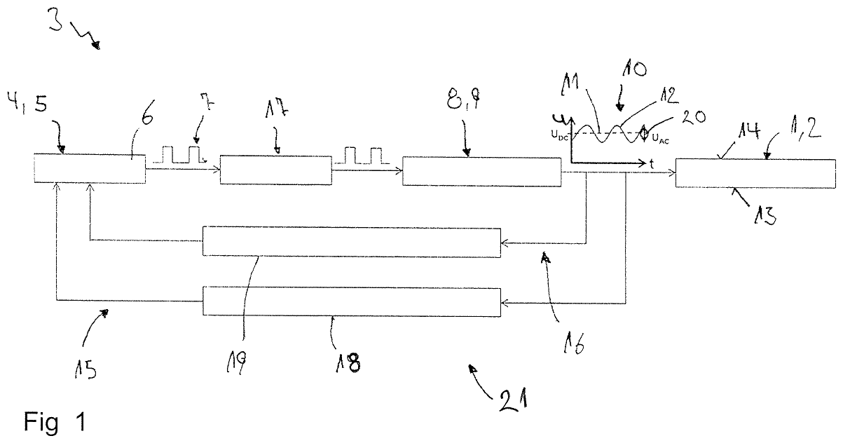

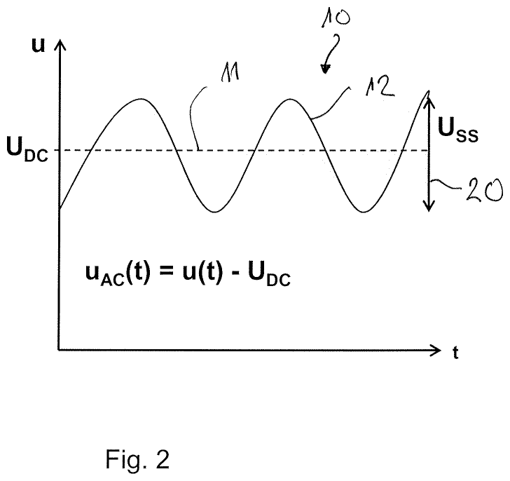

A thermoelectric module 1, for example a Peltier element 2, is typically part of a thermoelectric device 3, as it is shown for example in FIG. 1. The device 3 has a signal creator 6 or signal generator 6, which is integrated in a control means 4, in particular a processor 5 and which creates or generates, respectively, and outputs a pulse width modulated control signal 7 during operation. A filter means 8, which is embodied as a resonant circuit 9, also referred to as LC filter 9, is provided between the thermoelectric module 1 and the signal creator 6. The filter means 8 converts the pulse width modulated control signal 7, which is created by the signal creator 6, into an operating signal 10. The operating signal 10 has an operating voltage 12 or corresponds thereto, respectively, and is illustrated in FIG. 1 in a diagram, which is shown in an enlarged manner in FIG. 2. The x-axis corresponds to the course of time in this diagram, while the electrical voltage is applied on the y-axis. The time-dependent operating voltage 12 or the operating signal 10, respectively, is identified with u(t) in the diagram and consists of a direct voltage portion 11, illustrated by means of dashes and identified with “U_{DC}”in the diagram, and of a time-dependent alternating voltage portion. The alternating voltage portion thus corresponds to the operating voltage 12, minus the direct voltage portion 11, so that the following applies: u_{AC}(t)=u(t)−U_{DC}. In the shown example, the conversion occurs in such a way that the operating signal 10 or the operating voltage 12, respectively, has a sinusoidal course. The operating signal 10 is supplied to the thermoelectric module 1, in order to operate the latter. This means that the module 1 pumps heat during operation and thus has a cold side 13 as well as a warm side 14 due to the supply of the operating signal 10 to the module 1.

The filter means 8, in particular the resonant circuit 9, is embodied in such a way that the filtered or converted control signal 7, respectively, has a predetermined relative amplitude, which corresponds to the ratio between a peak-to-peak value 20 of the operating voltage 12, identified with U_{SS} in the diagram, and the sum of the direct voltage portion 11. The peak-to-peak value 20 thereby corresponds to the difference between a maximum and an, in particular following, minimum of the operating voltage 12. In the case of the shown example of a sinusoidal operating voltage 12, the peak-to-peak value 20 is thus twice the amplitude of the operating voltage 12. The filter means 8 is thereby embodied in such a way that the peak-to-peak value 20 is smaller than the direct voltage portion 11.

The operating signal 10 or the operating voltage 12, respectively, comprising the direct voltage portion 11 and the alternating voltage portion is additionally used to identify an electrical resistance, in particular an internal resistance, of the electric module 1. For this purpose, the operating signal 10 is tapped on the module 1. The identification of the resistance occurs in that a measurement of the direct voltage portion 11 and of the alternating voltage portion, suggested in FIG. 1 with a first branch 15 of a measuring means 21, and a measurement of the corresponding electrical currents, that is, a current measurement associated with the direct voltage portion 11 and a current measurement associated with the alternating voltage portion, suggested in FIG. 1 in a second branch 16 of the measuring means 21, are performed. These measurements or the measuring results, respectively, are supplied to the control means 4. The identification of the electrical resistance of the module 1 as a function of the measured voltages and currents occurs in the control means 4, in particular in consideration of the Seebeck effect. Based on the resistance, an estimation of the temperature of the module 1 additionally occurs on the cold side 13 and on the warm side 14.

In the shown example, an optional driver stage 17 is arranged between the control means 4, in particular signal creator 6, and the filter means 8. A voltage signal pre-processing means 18 can also be provided in the first branch 15, and/or a current signal pre-processing means 19 can be provided in the second branch 16.

It is possible by means of the shown device 3 and the corresponding method to identify the resistance of the module 1 continuously and thus permanently, so that the temperatures of the module 1 on the cold side 13 and/or on the warm side 14 can also be determined or estimated permanently, respectively. It is also conceivable to perform these identifications or determinations, respectively, in time intervals, which can be a few seconds. Due to the fact that the thermoelectric module 1 has no significant thermal changes within such time intervals due to the thermal inertia, the method can thus be performed in a simplified manner.

It is also possible by means of the device 3 and the method to perform the identification of the resistance of the module 1 during running operation of the module 1, that is, without interruption of the electrical supply, which is required for the operation of the module 1.

It is conceivable thereby to change a duty cycle of the pulse width modulated signal 7, in particular to adjust it to a constant value, during those phases, in which an identification of the electrical resistance of the module 1 occurs.

1. A method for operating a thermoelectric module, comprising:
creating a pulse width modulated control signal for controlling the thermoelectric module;
converting the control signal into an operating signal having a direct voltage portion and an alternating voltage portion;
supplying the operating signal for operating the thermoelectric module to the thermoelectric module; and
tapping the operating signal on the thermoelectric module and determining an electrical resistance of the thermoelectric module therefrom.

2. The method according to claim 1, wherein the control signal is converted into the operating signal via a filter mechanism.

3. The method according to claim 1, wherein the control signal is converted into the operating signal such that the alternating voltage portion of the operating signal has a sinusoidal course.

4. The method according to claim 1, wherein converting the control signal into the operating signal includes filtering higher harmonics of the pulse width modulated control signal.

5. The method according to claim 1, wherein the control signal is converted into the operating signal such that a peak-to-peak value of an operating voltage of the operating signal is smaller than a value of the direct voltage portion.

6. The method according to claim 1, further comprising temporarily adjusting a duty cycle of the pulse width modulated control signal for identification of the electrical resistance of the thermoelectric module to a constant value for a predetermined time period.

7. The method according to claim 6, wherein the predetermined time period is 10 milliseconds or less.

8. The method according to claim 1, wherein the electrical resistance is determined in time intervals of 15 seconds or less.

9. A thermoelectric device comprising:
a thermoelectric module configured to pump heat during operation
a signal creator configured to control the thermoelectric module, the signal creator providing a pulse width modulated control signal;
a filter mechanism arranged between and communicatively connected to the thermoelectric module and the signal creator, the filter mechanism configured to convert the pulse width modulated control signal into an operating signal having a direct voltage portion and an alternating voltage portion.

10. The thermoelectric device according to claim 9, further comprising a measuring mechanism configured to determine a voltage of the direct voltage portion, a voltage of the alternating voltage portion, and a respective electrical currents of the direct voltage portion and the alternating voltage portion.

11. The thermoelectric device according to claim 10, further comprising a voltage signal pre-processing mechanism disposed in a first branch of the measuring mechanism and a current signal pre-processing mechanism disposed in a second branch of the measuring mechanism.

12. The thermoelectric device according to claim 9, further comprising a processor in which the signal creator is integrated, the processor configured to determine an electrical resistance of the thermoelectric module based on the measured voltage of the direct voltage portion, the measured voltage of the alternating voltage portion, the measured electrical current of the direct voltage portion, and the measured electrical current of the alternating voltage portion.

13. The thermoelectric device according to claim 9, further comprising a driver stage arranged between the signal creator and the filter mechanism.

14. The method according to claim 1, further comprising:
measuring a voltage of the direct voltage portion and a voltage of the alternating voltage portion in a first branch of a measuring mechanism;
measuring an electrical current of the direct voltage portion and an electrical current of the alternating voltage portion in a second branch of the measuring mechanism.

15. The method according to claim 14, further comprising supplying the measured voltage of the direct voltage portion, the measured voltage of the alternating voltage portion, the measured electrical current of the direct voltage portion, and the measured electrical current of the alternating voltage portion to a control mechanism, and wherein the electrical resistance of the thermoelectric module is determined based on the measured voltage of the direct voltage portion, the measured voltage of the alternating voltage portion, the measured electrical current of the direct voltage portion, the measured electrical current of the alternating voltage portion, and the Seebeck effect via the control mechanism.

16. The method according to claim 1, further comprising determining a temperature of the thermoelectric module on a cold side and a temperature of the thermoelectric module on a warm side based on the determined electrical resistance of the thermoelectric module.

17. The method according to claim 2, wherein the filter mechanism is a resonant circuit.

18. The method according to claim 2, wherein the filter mechanism is an LC filter.

19. The method according to claim 5, wherein a relative amplitude of the operating signal defined by a ratio of the peak-to-peak value of the operating voltage to the value of the direct voltage portion is 0.10 to 0.40.

20. The method according to claim 6, wherein the constant value of the duty cycle is selected such that a thermal reaction of the module is negligible during the predetermined time period.
